(19) United States
(12) Patent Application Publication
(10) Pub. No.: US 2026/0043830 A1
(43) Pub. Date: Feb. 12, 2026

(54) DEBONDABLE TEST WAFER/PROBE CARD

(71) Applicant: ADEIA SEMICONDUCTOR BONDING TECHNOLOGIES INC., San Jose, CA (US)

(72) Inventors: Guilian Gao, Campbell, CA (US); Pawel Mrozek, San Jose, CA (US); Gaius Gillman Fountain, JR., Youngsville, NC (US)

(21) Appl. No.: 18/799,794

(22) Filed: Aug. 9, 2024

(51) Int. Cl. G01R 1/073; G01R 1/067; G01R 31/28

(52) U.S. Cl. CPC G01R 1/07342; G01R 1/06761; G01R 31/2889

(57) ABSTRACT

A probe card for probing a semiconductor substrate is disclosed. The probe card can include a probing element having a hybrid bonding surface that is configured to removably hybrid bond to a semiconductor element. The hybrid bonding surface of the probing element can include a nonconductive layer and contact pads at least partially embedded in the nonconductive layer. The contact pads of the probing element can be bonded to probe pads of the semiconductor element. Additionally, the nonconductive layer of the probing element can be bonded to a nonconductive layer of the semiconductor element. A conductive material can be deposited over the contact pads. The conductive material can comprise a lower melting point than the contact pads. The conductive material can comprise at least one of a low melting point metal and conductive polymer.

### BACKGROUND

### Field

This disclosure relates to semiconductor device structures and methods. In particular, some implementations are directed to methods and structures for testing semiconductor elements via probe pads by temporarily hybrid bonding a testing element to the semiconductor element.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Semiconductor devices have increased in complexity along with the need to reduce the possibility of damaging the testing surface of the semiconductor device during testing. However, it can be challenging to provide testing that adequately tests the features of a semiconductor device without damaging the bonding features of the semiconductor device. Accordingly, there remains a continuing demand for improved probing devices and processes.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In some implementations, a probe card for testing a semiconductor substrate can include: a probing element having a hybrid bonding surface that is configured to removably hybrid bond to a semiconductor element, the hybrid bonding surface of the probing element including a nonconductive layer and contact pads at least partially embedded in the nonconductive layer; wherein the contact pads of the probing element are configured to be bonded to probe pads of the semiconductor element; and wherein the nonconductive layer of the probing element is configured to be bonded to a nonconductive layer of the semiconductor element.

In some implementations, the probe card includes an optical device connected to the hybrid bonding surface. In some implementations, a conductive material is deposited over the contact pads. In some implementations, the conductive material is configured to be heated to bond the contact pads to the probe pads. In some implementations, the conductive material includes at least one of a low melting point metal and conductive polymer. In some implementations, the low melting point metal includes at least one of gallium, indium, and eutectic alloys. In some implementations, the conductive polymer includes polyacetylene (PA), polyaniline (PANI), polystyrene-sulphonate (PEDOT:PSS), polypyrrole (PPy), polythiophene (PT), and poly(o-phenylene-diamine) (PoPDA).

In some implementations, the probe card includes: a test interface substrate having a base layer, wherein the test interface substrate includes one or more vias extending through the test interface substrate; wherein the probing element includes a first surface and a second surface opposite the first surface, the first surface of the probing element attached to the base layer of the test interface substrate; and wherein the one or more vias electrically connect the test interface substrate and the probing element. In some implementations, the test interface substrate includes testing circuitry tests physical functionality, electrical connectivity and functionality, and optical functionality of the semiconductor element.

In some implementations, the base layer includes at least one of silicon, glass, and ceramic. In some implementations, the probe pads include input and output pads. In some implementations, the probing element includes one or more layers replicating an interposer configured to be bonded to the semiconductor element. In some implementations, the semiconductor element includes a device element.

In some implementations, the probe card includes elastic biasing members connected to the contact pads and configured to cause reversible contact between the contact pads of the probing element and the probe pads of the semiconductor element. In some implementations, the probe card includes a channel in communication with the contact pads, wherein the channels are configured for liquid metal injection for providing electrical communication between the probing element and the probe pads of the semiconductor element during testing of the semiconductor element.

In some implementations, a probe card for testing a semiconductor substrate includes: a probing element having a hybrid bonding surface that is prepared to removably hybrid bond to a semiconductor element, the hybrid bonding surface including a nonconductive layer and contact pads at least partially embedded in the nonconductive layer, wherein the contact pads of the probing element are configured to be bonded to probe pads of the semiconductor element, and wherein the nonconductive layer of the probing element is configured to be bonded to a nonconductive layer of the semiconductor element; and elastic biasing members connected to the contact pads and configured to cause reversible contact between the contact pads of the probing element and the probe pads of the semiconductor element.

In some implementations, a conductive material is deposited over the contact pads. In some implementations, the conductive material is configured to be heated to bond to the probe pads of the semiconductor element. In some implementations, the conductive material includes at least one of a low melting point metal and conductive polymer. In some implementations, the low melting point metal includes at least one of gallium, indium, and eutectic alloys. In some implementations, the conductive polymer includes polyacetylene (PA), polyaniline (PANI), polystyrene-sulphonate (PEDOT:PSS), polypyrrole (PPy), polythiophene (PT), and poly(o-phenylene-diamine) (PoPDA).

In some implementations, the probe card includes: a test interface substrate having a base layer, wherein the test interface substrate includes one or more vias extending through the test interface substrate; wherein the probing element includes a first surface and a second surface opposite the first surface, the first surface of the probing element attached to the base layer of the test interface substrate; and wherein the one or more vias electrically connect the test interface substrate and the probing element. In some implementations, the test interface substrate includes testing circuitry, wherein the testing circuitry tests physical functionality, electrical connectivity and functionality, and optical functionality of the semiconductor element.

In some implementations, the base layer includes at least one of silicon, glass, and ceramic. In some implementations, the probe pads include input and output pads. In some implementations, the probing element includes one or more layers replicating an interposer configured to be bonded to the semiconductor element. In some implementations, the semiconductor element includes a device element.

In some implementations, a probe card for testing a semiconductor substrate includes: a probing element having a hybrid bonding surface that is prepared to removably hybrid bond to a semiconductor element, the hybrid bonding surface including a nonconductive layer and contact pads at least partially embedded in the nonconductive layer, wherein the contact pads of the probing element are configured to be bonded to probe pads of the semiconductor element, and wherein the nonconductive layer of the probing element is configured to be bonded to a nonconductive layer of the semiconductor element; and a channel in communication with the contact pads, wherein the channels are configured for liquid metal injection for providing electrical communication between the probing element and the probe pads of the semiconductor element during testing of the semiconductor element.

In some implementations, the injected liquid metal includes at least one of gallium, indium, tin, zinc, bismuth, mercury, cadmium, thallium, and lead. In some implementations, a conductive material is deposited over the contact pads. In some implementations, the conductive material is configured to be heated to bond to the probe pads of the semiconductor element. In some implementations, the conductive material includes at least one of a low melting point metal and conductive polymer. In some implementations, the low melting point metal includes at least one of gallium, indium, and eutectic alloys. In some implementations, the conductive polymer includes polyacetylene (PA), polyaniline (PANI), polystyrene-sulphonate (PEDOT:PSS), polypyrrole (PPy), polythiophene (PT), and poly(o-phenylene-diamine) (PoPDA).

In some implementations, the probe card includes: a test interface substrate having a base layer, wherein the test interface substrate includes one or more vias extending through the test interface substrate; wherein the probing element includes a first surface and a second surface opposite the first surface, the first surface of the probing element attached to the base layer of the test interface substrate; and wherein the one or more vias electrically connect the test interface substrate and the probing element. In some implementations, the test interface substrate includes testing circuitry, wherein the testing circuitry tests physical functionality, electrical connectivity and functionality, and optical functionality of the semiconductor element. In some implementations, the base layer includes at least one of silicon, glass, and ceramic.

In some implementations, the probe pads include input and output pads. In some implementations, the probing element includes one or more layers replicating an interposer configured to be bonded to the semiconductor element. In some implementations, the semiconductor element includes a device element.

In some implementations, a method for testing a semiconductor element with a probing element includes: hybrid bonding a dielectric layer of a probing element to a dielectric layer of a semiconductor element and contact pads of the probing element to probe pads of the semiconductor element; and debonding the probing element from the semiconductor element.

In some implementations, the method includes preparing the dielectric layer of the probing element to weaken a bonding energy between the probing element and the semiconductor element. In some implementations, planarizing the dielectric layer of the semiconductor element includes chemical mechanical polishing. In some implementations, the method includes planarizing the dielectric layer of the semiconductor element along a bonding interface for a direct bonding process or a hybrid bonding process.

In some implementations, planarizing the dielectric layer to a flatness capable of the direct bonding process or the hybrid bonding process on the layer of dielectric. In some implementations, the method includes depositing a conductive material over the contact pads of the probing element.

In some implementations, the method includes heating the bonded probing element and the semiconductor element to cause the conductive material to connect the contact pads of the probing element to probe pads of the semiconductor element. In some implementations, the contact pads are at least partially embedded in the dielectric layer of the probing element.

In some implementations, a test assembly for testing a semiconductor substrate includes: a test interface substrate having a base layer, wherein the test interface substrate includes one or more vias extending through the test interface substrate; and a probing element including a first surface and a second surface opposite the first surface, the first surface of the probing element attached to the base layer of the test interface substrate, the probing element including routing layers and a hybrid bonding surface that is configured to removably hybrid bond to a semiconductor element, the hybrid bonding surface including a nonconductive layer and contact pads at least partially embedded in the nonconductive layer, wherein the contact pads of the probing element are configured to be bonded to probe pads of the semiconductor element, and wherein the nonconductive layer of the probing element is configured to be bonded to a nonconductive layer of the semiconductor element; wherein a conductive material is deposited over the contact pads; and wherein the one or more vias electrically connect the test interface substrate and the probing element.

In some implementations, the conductive material is configured to be heated to bond to the probe pads of the semiconductor element. In some implementations, the test interface substrate includes testing circuitry, wherein the testing circuitry tests physical functionality, electrical connectivity and functionality, and optical functionality of the semiconductor element. In some implementations, the base layer includes at least one of silicon, glass, and ceramic. In some implementations, the conductive material includes at least one of a low melting point metal and conductive polymer. In some implementations, the low melting point metal includes at least one of gallium, indium, and eutectic alloys. In some implementations, the conductive polymer includes polyacetylene (PA), polyaniline (PANI), polystyrene-sulphonate (PEDOT:PSS), polypyrrole (PPy), polythiophene (PT), and poly(o-phenylene-diamine) (PoPDA).

In some implementations, the probing element further includes elastic biasing members attached to the contact pads, wherein the elastic biasing members are configured to provide a resistance force to the contact pads for physically contacting the probe pads. In some implementations, the probing element further includes channels in communication with the contact pads, wherein the channels are configured for liquid metal injection for providing electrical communication between the probing element and the probe pads of the semiconductor element during testing of the semiconductor element.

In some implementations, the injected liquid metal includes at least one of gallium, indium, tin, zinc, bismuth, mercury, cadmium, thallium, and lead. In some implementations, the probe pads include input and output pads. In some implementations, the probing element includes one or more layers replicating an interposer configured to be bonded to the semiconductor element. In some implementations, the base layer is attached to the test interface substrate via a conductive adhesive.

In some implementations, a test assembly for testing a semiconductor substrate, the assembly including: a test interface substrate having a base layer, wherein the test interface substrate includes one or more vias extending through the test interface substrate; and a probing element including a first surface and a second surface opposite the first surface, the first surface of the probing element attached to the base layer of the test interface substrate, the probing element including routing layers and a hybrid bonding surface that is configured to removably hybrid bond to a semiconductor element, the hybrid bonding surface including a nonconductive layer and contact pads at least partially embedded in the nonconductive layer, wherein the contact pads of the probing element are configured to be bonded to probe pads of the semiconductor element and wherein the nonconductive layer of the probing element is configured to be bonded to a nonconductive layer of the semiconductor element; wherein the one or more vias electrically connect the test interface substrate and the probing element.

In some implementations, a conductive material is deposited over the contact pads. In some implementations, the conductive material is configured to be heated to bond to the probe pads of the semiconductor element. In some implementations, the conductive material includes at least one of a low melting point metal and conductive polymer. In some implementations, the low melting point metal includes at least one of gallium, indium, and eutectic alloys. In some implementations, the conductive polymer includes polyacetylene (PA), polyaniline (PANI), polystyrene-sulphonate (PEDOT:PSS), polypyrrole (PPy), polythiophene (PT), and poly(o-phenylene-diamine) (PoPDA).

In some implementations, the test interface substrate includes testing circuitry, wherein the testing circuitry is configured to test functionalities of the probe pads of the semiconductor element. In some implementations, the base layer includes at least one of silicon, glass, and ceramic.

In some implementations, the probing element further includes elastic biasing members attached to the contact pads, wherein the elastic biasing members are configured to provide a resistance force to the contact pads for physically contacting the probe pads. In some implementations, the probing element further includes channels in communication with the contact pads, wherein the channels are configured for liquid metal injection for providing electrical communication between the probing element and the probe pads of the semiconductor element during testing of the semiconductor element. In some implementations, the injected liquid metal includes at least one of gallium, indium, tin, zinc, bismuth, mercury, cadmium, thallium, and lead.

In some implementations, the probe pads include input and output pads. In some implementations, the probing element includes one or more layers replicating an interposer configured to be bonded to the semiconductor element. In some implementations, the base layer is attached to the test interface substrate via a conductive adhesive.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 is a schematic side sectional view of a conventional semiconductor element.

FIG. 2 is a schematic side sectional view of a semiconductor element and interposer.

FIG. 3 is a schematic side sectional view of a test assembly having a probing element, according to various implementations.

FIG. 4 is a schematic cross-sectional side view of the semiconductor element of FIG. 2 and the probing element of FIG. 3 bonded together, according to some implementations.

FIG. 5A is a schematic top view of a device wafer having probe pads.

FIG. 5B is a schematic bottom view of a test assembly including probing elements with contact pads for contacting the probe pads of FIG. 5A.

FIG. 5C is a schematic cross-sectional side view of the device wafer of FIG. 5A and the probing element of FIG. 5B bonded together.

FIG. 6A is a schematic top view of a device wafer having probe pads.

FIG. 6B is a schematic bottom view of a test assembly including probing elements with channels for contacting the probe pads of FIG. 6A.

FIG. 6C is a schematic cross-sectional side view of the device wafer of FIG. 6A and the probing element of FIG. 6B bonded together.

FIG. 7A is a schematic cross-sectional side view of two elements prior to direct hybrid bonding.

FIG. 7B is a schematic cross-sectional side view of a bonded structure including the two elements shown in FIG. 7A after direct hybrid bonding.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and includes other uses of the inventions and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments can comprise several novel features. No single feature is solely responsible for its desirable attributes or is essential to practicing the inventions herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

There is significant demand for reducing and/or eliminating the damage to semiconductor elements when probe testing. Conventional probing methods involve the use of specialized equipment known as probe stations or probe testers. These systems facilitate electrical contact with the semiconductor element's internal circuits via probe needles and/or pins. The probing process includes several stages, such as initial contact, signal transmission, data acquisition, and result analysis. Each stage is designed to validate different aspects of the semiconductor element's performance and integrity. Probing equipment can include a probe station comprising a mechanical apparatus that holds the semiconductor element securely in place during testing. The probe stations further include a microscope and/or cameras for precise alignment and positioning of probe needles. Additionally, the probing equipment can further include a probe card which is an interface containing multiple probe needles or pins that make physical contact with the contact pads of the semiconductor element. The probe card is designed to match the layout of the contact pads of the semiconductor element. Lastly, the probing equipment can include a signal generator and/or analyzer which are devices used to generate test signals and analyze the response of the semiconductor element. The signal generator and/or analyzer are connected to the probe card through electrical wires and/or cables.

During the probing process, the semiconductor elements are placed on the probe station's platform and aligned with assistance of a microscope and/or cameras. This ensures that the probe needles accurately contact the pads of the semiconductor elements. Next, the probe card is positioned above the semiconductor elements. Using fine adjustment controls, the probe needles are lowered until they make contact with the pads of the semiconductor elements. The force applied is monitored to prevent damage to the semiconductor element, however, the probe needles can scratch the pads. Consequently, the semiconductor elements require additional processing and/or reconditioning before they can be prepared for hybrid bonding. Test signals are transmitted into the semiconductor elements through the probe needles. These signals are designed to activate various circuits within the semiconductor elements, simulating operational conditions. The semiconductor element's responses to the test signals are captured and recorded by circuitry included in the probe card. This data includes voltage levels, current flows, and timing information, which are important for assessing the performance of the semiconductor elements. The acquired data is then analyzed to determine the functionality and performance of the semiconductor elements. This analysis identifies defects such as open circuits, short circuits, and/or parameter deviations from specifications.

Probing techniques can also include measuring specific electrical parameters, such as threshold voltage and/or leakage current, to ensure they fall within acceptable ranges. Additionally, functional testing of the semiconductor element assesses the ability of the semiconductor element to perform its intended functions under various conditions. Functional tests often include checking logic operations, memory read/write cycles, and/or communication protocols. In a burn-in testing, the semiconductor element is subjected to elevated temperatures and voltages to accelerate aging and reveal potential reliability issues. Probes monitor the behavior of the semiconductor element throughout the burn-in period. Lastly, dynamic testing can utilize real-time signals transmitted into the semiconductor element to mimic actual operating conditions. This tests the performance of the semiconductor element under dynamic loads and high-frequency operation.

U.S. Patent Publication 2023/0375613, which is incorporated by reference herein, discloses test elements that can determine whether a new type of device die functions as expected while testing limited quantities of dies before production. For example, in operation, testing circuitry can transmit one or more signals to active circuitry (e.g., one or more transistors) through directly bonded conductive contact pads of the testing chip and the semiconductor element, or, in the alternative, by way of lateral traces and/or vertical interconnects in the chip. The transmitted signal(s) can probe portions of the active circuitry (e.g., one or more transistors to be probed or tested), and the tested active circuitry can emit a return signal that is conveyed from the semiconductor element to the testing circuitry which can be processed by the testing circuitry to determine whether the tested active circuitry of the semiconductor element is functional and/or non-functional. By contrast, various implementations of the present application are directed to a probing device having a probing element to test the physical functionality, electrical connectivity and functionality, and optical functionality of the semiconductor element of each die region on a wafer rather than providing a testing element bonded to a semiconductor element to test the logic functionality of a semiconductor element. Additionally, the probing device of the present application can probe every wafer from a manufacturing line before singulation of the wafer in order to identify known good dies (KGDs).

As mentioned above, one of the challenges in the probing process is the potential for damage to the semiconductor element caused by the probe needles. Probe needles are designed to make contact with the probe pads of the semiconductor element to facilitate electrical testing. In some testing procedures, the probe needle has to scrape through a preliminary layer, such as an oxide layer, formed (e.g., naturally formed) on the contact pad (e.g., aluminum oxide on aluminum (Al) pads) in order to access the metal of the contact pad. The probing process can cause physical damage to the contact pads, leading to scratches, burrs, and/or gouges on the semiconductor element, and/or short circuits caused by debris from damaged contact pads (commonly known as probe marks). Such probe marks can be tolerated by wire bonding. For flip chip soldering, the probe marks are covered over by a metal layer commonly known as under-bump metallurgy (UBM). The UBM layer is deposited after the wafer probing process. The UBM layer fabrication is time-consuming and add costs. For hybrid bonding, such damage can be repaired by methods described in U.S. Pat. No. 11,355,404, which is incorporated by reference herein, which can be time consuming and require additional steps. Once the repair is completed, additional oxide layers are deposited, which are then planarized, and conductive material (e.g., copper) is added. Thus, there is a continued need for improving the testing instrumentations for semiconductor elements without damaging said semiconductor elements and/or contact pads of said semiconductor elements.

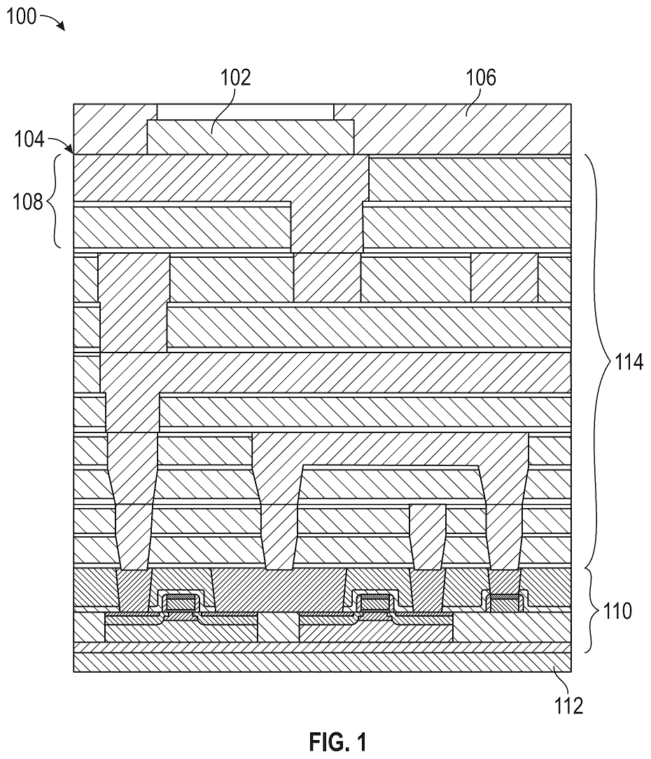

FIG. 1 illustrates a schematic side sectional view of a conventional semiconductor element 100. The semiconductor element 100 can include probe pads 102 along a surface 104 of the semiconductor element 100. The surface 104 can also be a hybrid bonding surface which can be hybrid bonded to additional elements. The probe pads 102 can comprise a layer of aluminum for testing, which can be surrounded by an inorganic dielectric layer 106. Aluminum can form a very dense oxide layer naturally when exposed to air. The oxide layer forms a natural corrosion barrier that protects the pads (e.g., probe pads 102) from further oxidation and corrosion. However, it is insulating and must be broken through for electrical testing. The probe pads 102 can be deposited on top of routing layers 108, which comprises a conductive material (e.g., copper) and a non-conductive material (i.e., a dielectric). The semiconductor element 100 can further include a substrate 112 (e.g., a silicon substrate) and device layers 110 atop the substrate 112. Metallization layers 114 can be formed which extend from the device layers 110 to the surface 104. The routing layers 108 can be an uppermost section of the semiconductor element 100 and include the surface 104 (also mentioned herein as a “wafer surface”). During conventional testing methods, probe needles of a probing card penetrate (e.g., scratch, scrape, scrub, etc.) the metal oxide layer (e.g., aluminum oxide on aluminum pads) to contact the metal of the probe pads 102, which can introduce scratch marks onto the probe pads 102. The scratch marks on the probe pads 102 can hinder the hybrid bonding process. For example, conventional testing methods can result in damage (e.g., burrs) that can be approximately 2 μm high. Said damage can require substantial work to repair and/or recondition the probe pads 102 for a hybrid bonding process. Additionally, to prepare for the hybrid bonding process, the aluminum layer (i.e., probe pads 102) can be removed to reduce the cost of hybrid bonding. The surface 104 can be planarized and an additional conductive material (e.g., copper) can be added to surface 104 to serve as conductive contacts for hybrid bonding. An additional challenge for testing is that the pitch of the probe pads 102 can be typically around 50 μm by 50 μm or larger. Further scaling of the probe pads 102 also poses an additional challenge.

With adoption of hybrid bonding technology, the traditional top aluminum layer can be replaced with a copper (Cu) layer to eliminate the cost associated with planarizing the wafer surface 104 for hybrid bonding. Moreover, hybrid bonding enables bonding pitch below 1 μm. As a result, some of the metal routing layers currently present in a semiconductor device (e.g., semiconductor element 100) can be eliminated or moved from the device (e.g., semiconductor element 200) to an interposer (e.g., interposer 216). The routing layers 108 can be either relocated to an interposer (e.g., interposer 216) and/or eliminated from the device wafer. With such design change, the test wafer design needs to be changed to enable functional testing of the device wafer in the absence of layer 108.

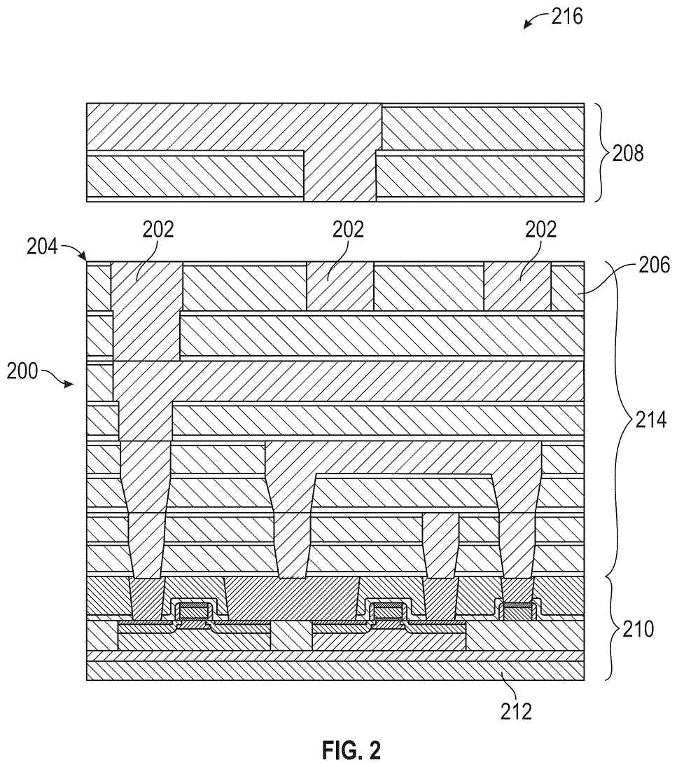

FIG. 2 illustrates a schematic side sectional view of a semiconductor element 200 of a wafer for testing. A wafer can comprise a plurality of semiconductor element 200 prior to singulation. The semiconductor element 200 can be similar to semiconductor element 100. For example, the semiconductor element 200 can include device layers 210 and a substrate 212. However, rather than being deposited on the device layers 210 of the semiconductor element 200, the routing layers 208 of the metallization layers 214, which are similar to the routing layers 108, can be provided as a separate interposer 216. The interposer 216 can improve optimization and/or reduce costs. Similar to the semiconductor element 100, the semiconductor element 200 can include a surface 204. The surface 204 can include probe pads 202 and nonconductive layers 206. The surface 204 can also serve as a hybrid bonding surface for hybrid bonding the semiconductor element 200 to additional elements. The probe pads 202 can comprise a part of a copper routing layer. The probe pads 202 can be at least partially embedded in the nonconductive layers 206. By moving the routing layers 208, which are similar to routing layers 108 of semiconductor element 100, to interposer 216, an improved probing method compatible with the new structure of the semiconductor element 200 can be provided. Also, a change from probe pads 102 to the probe pads 202 (e.g., the change in pitch) can enable metal contact features at micron or sub-micron level, whereas current convention probing methods cannot shrink to such small sizes. An improved probe card and/or assembly enabled to test probe pads 202, which replace probe pads 102, and with some of the outer routing layers removed into an interposer is disclosed herein.

As described above, the probe pads 202 can comprise a much smaller pitch than probe pads 102. The use of hybrid bonding techniques (such as Direct Bond Interconnect, or DBI®, techniques commercially available from Adeia of San Jose, CA) can enable high density connections between the improved probe card and probe pads 202 (e.g., small or fine pitches for regular arrays). For example, the pitch of the probe pads 202, can be less than 40 μm, less than 20 μm, less than 10 μm, less than 5 μm, less than 2 μm, less than 1 μm, or even less than 0.5 μm. Additionally, the probe pads 202 can comprise input and output pads for testing the physical functionality, electrical connectivity and functionality, and/or optical functionality of the semiconductor element 200. Input/output pads (I/O pads) can be utilized as interface points for electrical signals, power, and ground connections. Additionally, I/O pads facilitate signal transmission, power supply, grounding, and/or data communication in the semiconductor element 200. As explained above, the probe pads 202 can provide contact points for electrical signals. During wafer-level testing, contact probe pads 202 allow for test equipment to transmit and/or apply input signals (e.g., test signals) to activate the semiconductor element 200 and measure output responses of the semiconductor element 200. This process verifies the physical functionality of the semiconductor element 200, checks electrical characteristics (e.g., electrical connectivity and functionality), optical characteristics (e.g., optical functionality), and/or ensures reliability through stress testing like burn-in. Additionally, an electrical response from the semiconductor element 200 in response to a test signal can be measured. The electrical response can include at least one of voltage, current, and/or resistance. Wafer-level testing can also include comparing a measured electrical response to a predetermined standard response for a properly functioning semiconductor element. Automated test equipment can use I/O pads to conduct extensive, automated testing, ensuring performs correctly before integration into electronic devices by identifying known good dies (KGDs) prior to simulation of a wafer. In some implementations, the semiconductor element 200 can comprise microelectronic elements, such as semiconductor elements, including, for example, integrated device dies, wafers, passive devices, discrete active devices such as power switches, MEMS, etc.

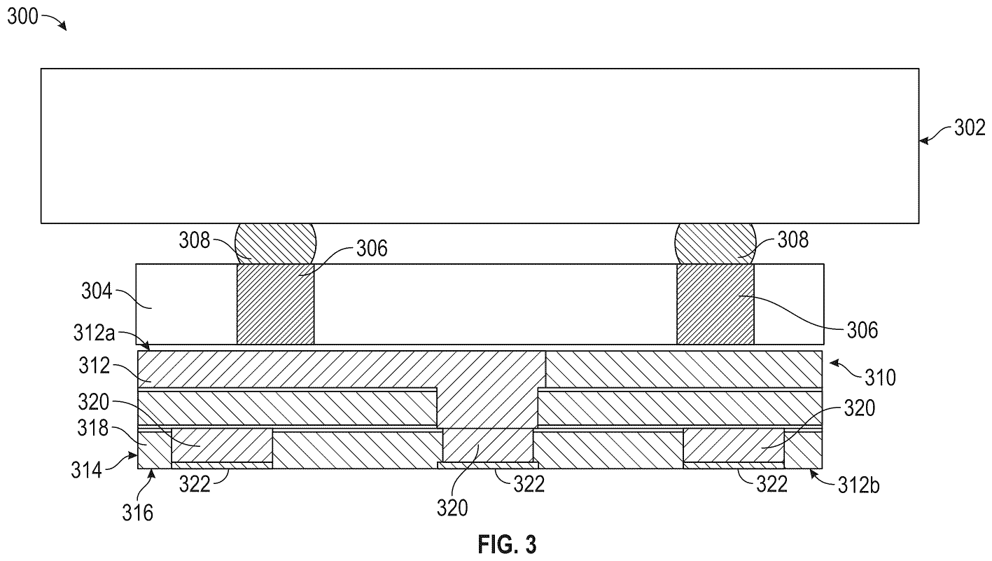

FIG. 3 illustrates a test assembly 300 (also mentioned herein as a “probe card” and/or “probing device”) for testing the semiconductor element 200 shown in FIG. 2. The test assembly 300 can comprise a test interface substrate 302 having multiple layers. The test interface substrate 302 can also comprise testing circuitry to test the connectivity and/or physical integrity of the semiconductor element 200. The test interface substrate 302 can comprise a substrate having a nonconductive or insulating base substrate with conductive routing traces (not shown) (e.g., at least partially embedded traces), such as a laminate substrate, a printed circuit board (PCB) substrate, a semiconductor interposer, a flexible substrate comprising a polymer with embedded traces, or any other suitable substrate.

The test interface substrate 302 can be bonded (e.g., by solder or another conductive adhesive) to a probing element 310 that can be removably hybrid bonded to the semiconductor element 200. The test assembly 300 can test a plurality of semiconductor element 200 contained on a wafer prior to singulation of the wafer. The probing element 310 can includes a base layer 304 comprised of silicon, glass, and/or ceramic. The base layer 304 can include vias 306, which can extend through the base layer 304. A conductive adhesive 308 (e.g., solder) can connect the vias 306 to the test conductive traces of the test interface substrate 302, forming an electrical connection between the test interface substrate 302 and the probing element 310. In some implementations, the vias 306 can extend through the base layer 304 and connect the base layer 304 to routing layers 312.

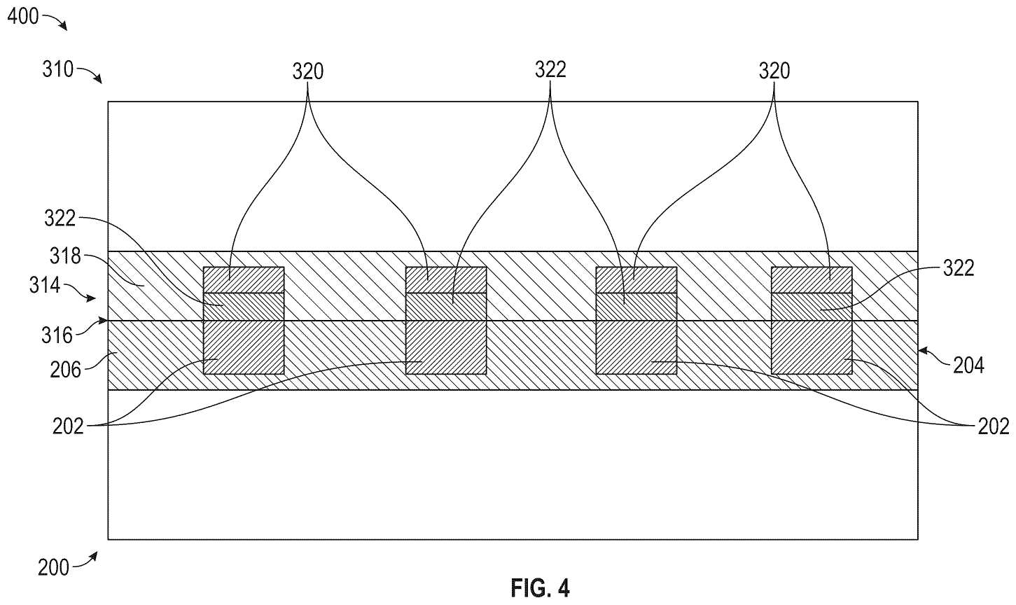

The routing layers 312 can comprise a first surface 312a and a second surface 312b opposite the first surface 312a. The first surface 312a of the routing layers 312 can be attached to the base layer 304. In some implementations, the routing layers 312 (which include dielectric and metal layers) can be deposited onto the base layer 304. In other implementations, the routing layers 312 are alternatively bonded to the base layer 304, e.g., using a transfer direct bonding process. The routing layers 312 can further include a hybrid bonding layer 314 that can be closer to the second surface 312b than the first surface 312a. The hybrid bonding layer 314 can include nonconductive layers 318 and contact pads 320. The contact pads 320 can be at least partially embedded in the nonconductive layers 318. Field regions of the hybrid bonding layer 314 can extend between and partially or fully surround the contact pads 320. The nonconductive layers 318 can comprise layers of non-conductive materials suitable for direct bonding, as described herein, and opposing field regions are directly bonded to one another without an adhesive. The contact pads 320 of the probe element 310 can be bonded to probe pads 202 of the semiconductor element 200 without intervening solder or conductive adhesive. Additionally, the nonconductive layers 318 of the probing element 310 can be bonded to the nonconductive layer 206 of the semiconductor element 200. In some implementations, the probing element 310 can comprise one or more layers (e.g., routing layers 312) which can serve as an interposer between the test interface substrate 302 and the semiconductor element 200 of FIG. 2. The routing layers 312 of the probing element 310 can be bonded to the semiconductor element 200, while replicating interposer 216 (e.g., the interposer 216 comprising routing layers 208). As mentioned above, the hybrid bonding layer 314 can removably hybrid bond to the semiconductor element 200 along a hybrid bonding interface 316 (see FIG. 4).

In some implementations, an optical device can be incorporated into the test assembly 300 for testing switching components for co-packaged optics. The optical interface of the optical device can be coplanar with the second surface 312b. The optical device can be passive components such as waveguides, grating couplers and/or splitters, it can also be active component such as transmitters and receivers. In addition, optical microscope, laser interferometers, optical probes, and/or a camera system can also be incorporated into the test assembly 300 configurations. An optical microscope allows for a visual inspection of contact points and alignment of the probing element 310 with the semiconductor element 200. The microscope provides magnification and illumination to help ensure that the probing element 310 is accurately positioned on the probe pads 202. This visual inspection can identify any misalignment, probe damage, or debris that could affect the integrity of the electrical tests. Modern optical microscopes can include digital imaging capabilities, enabling the capture and analysis of high-resolution images for documentation and further examination. Laser interferometers can be optical devices utilized for precisely measuring the contact between the probing element 310 and the surface 204 of the semiconductor element 200. Laser interferometers can split a laser beam into two paths, with one path reflecting off the probing element 310 and the other off the surface 204. The interference pattern generated by the recombined beams provides measurements of distance and alignment. This precision can ensure consistent and reliable contact during testing. Optical probes can detect light emissions from the semiconductor element 200 during testing. The optical probes can capture luminescence, such as electroluminescence or photoluminescence, which provides information about the electronic properties and behavior of the semiconductor element 200. For example, optical probes can help identify defects, measure carrier lifetimes, and evaluate the performance of light-emitting devices like LEDs. By analyzing the emitted light, users can gain insights into the quality and functionality of the semiconductor material of the semiconductor element 200 without making direct electrical contact, thereby preserving the integrity of the semiconductor element 200. High-resolution camera systems can be integrated with the test assembly 300 to capture detailed images and videos of the probing area (e.g., the semiconductor element 200). The camera systems can document the positioning and condition of the probing element 310 and the probe pads 202. The visual documentation can be utilized for quality control, troubleshooting, and/or process optimization. Advanced camera systems can include features like autofocus, image stabilization, and software for automated image analysis. By providing visual records, the camera systems can help ensure that the testing process is accurate and reproducible, ultimately improving the reliability and yield of semiconductor testing.

In some implementations, a conductive material 322 can be deposited over the contact pads 320 so that a relatively weak bond can be formed to facilitate removal of the probing element after probing. The conductive material 322 along with parts of or the whole probing element 310 can be heated to facilitate a bond between the contact pads 320 of the probing element 310 to the probe pads 202 of the semiconductor element 200. The conductive material 322 can comprise a low melting point metal such as gallium, indium, and/or eutectic alloys (e.g., Ga₇₈In₂₂ and/or Ga_{86.5}Sn_{13.5}). A eutectic alloy is a homogeneous mixture of two or more elements that solidifies at a single, specific temperature, known as the eutectic temperature, which is lower than the melting points of the individual components. Eutectic alloys possess a microstructure with fine, interspersed phases, enhancing properties like strength and hardness. Examples of eutectic alloys include lead-tin (Pb—Sn) used in soldering, aluminum-silicon (Al—Si) for casting, and gold-silicon (Au—Si) in semiconductor bonding. Eutectic alloys are utilized because of their lower melting points, predictable solidification behavior, and improved mechanical properties. For example, the conductive material 322 can include eutectic alloys like EGaIn (Ga₇₈In₂₂) with a melting point of 15.5° C., EGaSn (Ga_{86.5}Sn_{13.5}) with a melting point of 20.5° C., EGaSnZn (Ga₈₆Sn₁₁Zn₃) with a melting point of 14.9° C., and other alloys with melting point below 200° C.

In other implementations, the conductive material 322 can comprise a conductive polymer. A conductive polymer can be an electrically conductive organic polymer capable of conducting electricity, combining the flexibility and lightweight nature of plastics with the electrical properties of metals or semiconductors. These polymers, such as polyaniline (PANI), polypyrrole (PPy), and PEDOT, achieve conductivity through conjugated double bonds and doping. Conductive polymers can be used in applications like organic light-emitting diodes (OLEDs), sensors, batteries, antistatic coatings, and/or flexible electronics due to their processability, chemical versatility, and ability to be tailored for specific properties. Regarding conductive material 322, the conductive polymer can comprise polyacetylene (PA), polyaniline (PANI), polystyrene-sulphonate (PEDOT:PSS), polypyrrole (PPy), polythiophene (PT), and poly(o-phenylene-diamine) (PoPDA).

In preparing for hybrid bonding, the hybrid bonding layer 314 of the probing element 310 can be planarized and treated (e.g., cleaned and/or exposed to a plasma and/or etchants) to reduce the bonding energy between the hybrid bonding layer 314 and the semiconductor element 200 formed during the hybrid bonding process. For example, the hybrid bonding layer 314 can be terminated with a species after activation or during activation (e.g., during the plasma and/or etch processes) to weaken the bonding energy so that the probing element 310 can be easily removed after the probing process is complete. An annealing process during hybrid bonding can cause the conductive material 322 and the probe pads 202 to expand and contact one another to form a direct bond.

FIG. 4 schematically illustrate cross-sectional side views of probing element 310 of the test assembly 300 and semiconductor element 200 after a process for forming a directly bonded structure 400, and more particularly a hybrid bonded structure, according to some implementations. The test assembly 300, and particularly the probing element 310, can be formed and bonded at the wafer level such that the probing element 310 of the test assembly 300 can bond to the entire device wafer to test a plurality of devices (e.g., a plurality of semiconductor elements 200) all at once. To do so, the surface 312b of the nonconductive layers 318 can be treated to limit and/or reduce the bond energy and the bonds formed during an annealing step so that the probing element 310 can be easily removed from the device wafer after probing without causing damage to the devices being tested. In some implementations, the surface 204 of the non-conductive layer 206 on the device wafer can also be treated to limit and/or reduce the bond energy and the bonds formed during the annealing step. The bond energy is a measure of the strength of the bond between the two surfaces. In some implementations, the resulting bonding energy between the nonconductive layers 318 of the probing element 310 and the nonconductive layer 206 of the semiconductor element 200 can be between approximately 1 to 150 mJ/m2, between approximately 5 to 145 mJ/m2, between approximately 10 to 140 mJ/m2, between approximately 15 to 135 mJ/m2, between approximately 20 to 130 mJ/m2, between approximately 25 to 125 mJ/m2, between approximately 30 to 120 mJ/m2, between approximately 35 to 115 mJ/m2, between approximately 40 to 110 mJ/m2, between approximately 45 to 105 mJ/m2, between approximately 50 to 100 mJ/m2, between approximately 50 to 150 mJ/m2, between approximately 50 to 200 mJ/m2, between approximately 50 to 250 mJ/m2, between approximately 50 to 300 mJ/m2, between approximately 50 to 350 mJ/m2, between approximately 50 to 400 mJ/m2, between approximately 50 to 450 mJ/m2, between approximately 50 to 500 mJ/m2, between approximately 50 to 550 mJ/m2, between approximately 50 to 600 mJ/m2, between approximately 50 to 650 mJ/m2, between approximately 50 to 700 mJ/m2, or between approximately 50 to 750 mJ/m2. In some implementations, the resulting bonding energy between the nonconductive layers 318 of the probing element 310 and the nonconductive layer 318 can be at least 750 mJ/m2, at least 700 mJ/m2, at least 650 mJ/m2, at least 600 mJ/m2, at least 550 mJ/m2, at least 500 mJ/m2, at least 450 mJ/m2, at least 400 mJ/m2, at least 350 mJ/m2, at least 300 mJ/m2, at least 250 mJ/m2, at least 200 mJ/m2, at least 150 mJ/m2, at least 140 mJ/m2, at least 130 mJ/m2, at least 120 mJ/m2, at least 110 mJ/m2, at least 100 mJ/m2, at least 90 mJ/m2, at least 80 mJ/m2, at least 70 mJ/m2, at least 60 mJ/m2, at least 50 mJ/m2, at least 40 mJ/m2, at least 30 mJ/m2, at least 20 mJ/m2, at least 10 mJ/m2, or at least 1 mJ/m2. In other implementations, the test assembly 300 can be made to step through one or more regions have semiconductor elements 200 (i.e., step through a wafer comprising a plurality of semiconductor elements 200).

As explained above, the conductive material 322 can be deposited onto the contact pads 320 prior to the annealing step. During the annealing process, the probing element 310 can be bonded to the semiconductor element 200 by heating the bonded structure 400 which causes the contact pads 320 to expand and electrically and/or mechanically connect to the probe pads 202 to form a hybrid bond. Additionally, the conductive material 322 can be heated above the melting point of the conductive material 322 causing the conductive material 322 to melt and form a weak bond with the opposing probe pads 202. In some implementation, the hybrid bond comprises a copper-to-copper connection but one that makes only a weak bond energy.

The test interface substrate 302 having testing circuitry can conduct any of the testing methods considered above. Once testing is complete, the probing element 310 can be debonded from the semiconductor element 200. The semiconductor element 200 can be reconditioned and prepared for direct bonding (e.g., hybrid bonding) by polishing, for example, by chemical mechanical polishing (CMP), etching, etc. As mentioned above, including the conductive material 322 reduces the bond energy formed during hybrid bonding of the contact pads 320 to the probe pads 202. Without the conductive material 322, for example, if a typical copper-to-copper was formed with higher bond energy, the debonding of the contact pads 320 and probe pads 202 could damage the semiconductor element 200.

Reconditioning semiconductor elements following a temporary bonding testing cycle can provide for the surface properties used for any subsequent bonding. As described above, this process involves several techniques, including chemical mechanical polishing (CMP) and etching, which can remove defects, smooth surfaces, and/or prepare semiconductor elements for subsequent processing steps. Following the debonding from the probing element 310, the surface 204 of the semiconductor element 200 can be subjected to a light or tough CMP process to prepare the surface 204 for subsequent hybrid bonding. In some implementations, the surface 204 can undergo an activation process.

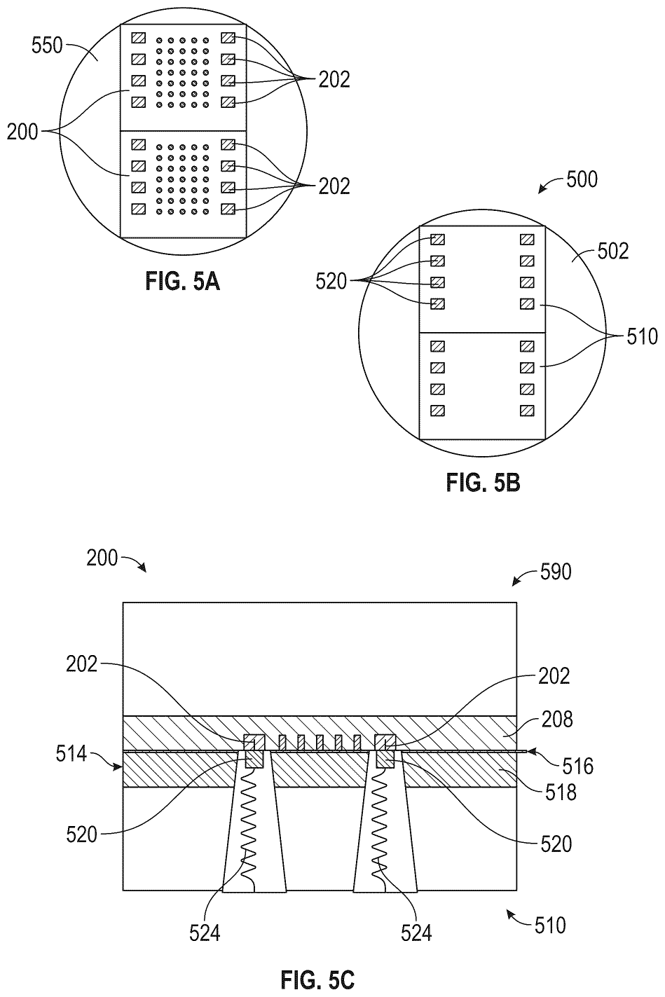

FIGS. 5A-5C illustrate various views of another implementation of a test assembly 500 and device wafer 550. The test assembly 500 can be utilized, for example, for testing a device wafer with probe pad size of tens of microns or larger. The test assembly 500 can be used to test the device wafer 550. FIG. 5A illustrates a top schematic view of the device wafer 550. In some implementations, the device wafer 550 can include a large number of semiconductor elements (e.g., semiconductor element 200 having probe pads 202) prior to singulation of the device wafer 550. Before and/or after testing, the device wafer 550 can be diced to form the semiconductor element 200 having probe pads 202. For ease of illustration, the device wafer 550 can be shown as containing two unsingulated semiconductor element 200 having probe pads 202. FIG. 5B illustrates and bottom view of the test assembly 500 showing contact pads 520. FIG. 5C schematically illustrates a cross-sectional side view of probing element 510 of the test assembly 500 and semiconductor element 200 after a process for forming a directly bonded structure 590, and more particularly a hybrid bonded structure, according to some implementations. Unless otherwise noted, components of FIGS. 5A-5C can be the same as or generally similar to like-numbered components of FIGS. 3-4. For example, the test assembly 500 can include a test interface substrate 502, a base layer (see base layer 304 in FIG. 3), vias (see vias 306 in FIG. 3), conductive adhesive (see conductive adhesive 308 in FIG. 3), a probing element 510, layers 512, bonding surface 514, bonding interface 516, nonconductive layers 518, and contact pads 520. In some implementations, the entirety of the device wafer 550 can be contacted and tested at the same time by the probing element 510.

As shown in FIG. 5C, the probing element 510 can be bonded (e.g., direct bonding) to the semiconductor element 200 of the device wafer 550. The probing element 510 can include a bonding surface 514 having nonconductive layers 518 (i.e., dielectric layers) in which the contact pads 520 are at least partially embedded therein. The nonconductive layers 518 can comprise layers of non-conductive materials suitable for direct bonding, as described herein. A dielectric bond can be formed between the nonconductive layers 518 of the probing element 510 and nonconductive layers 206 of the semiconductor element 200 along a bonding interface 516. In some implementations, the nonconductive layers 518, similar to nonconductive layers 318, and, in some implementations, the nonconductive layer 206, can be treated to weaken the bond formed between nonconductive layers 518 and nonconductive layers 206. Additionally, the contact pads 520 of the probing element 510 can be in contact with elastic biasing members 524 (e.g., springs, an expandable material, a gas, etc.) for applying a force to the contact pads 520. The elastic biasing members 524 can provide a resistive force to the contact pads 520 to physically press the contact pads 520 against the probe pads 202 of the semiconductor element 200. In some implementations, the elastic biasing members 524 can be mechanically joined to the contact pads 520. The elastic biasing members 524 can provide uniform contact between the contact pads 520 and the probe pads 202. Following testing, the probing element 510 can be debonded from the semiconductor element 200 by separating the nonconductive layers 518 from the nonconductive layers 206. Additionally, the probe pads 202 and nonconductive layers 206 can be reconditioned to prepare the semiconductor element 200 for processing and/or bonding to the interposer 216. By utilizing the elastic biasing members 524, damage to the probe pads 202 can be minimized and/or eliminated. Thus, the weakened dielectric bond can be paired with the resistive force of the elastic biasing members 524 to test the semiconductor element 200 without damaging the probe pads 202 and/or the semiconductor element 200. In some implementations, an actuator or the like can compress the elastic biasing members 524 to disconnect and/or separate the contact pads 520 from the probe pads 202 of the semiconductor element 200. For example, a compressive force can be applied to the elastic biasing members 524 by an actuator which assists in debonding the probing element 510 from the semiconductor element 200.

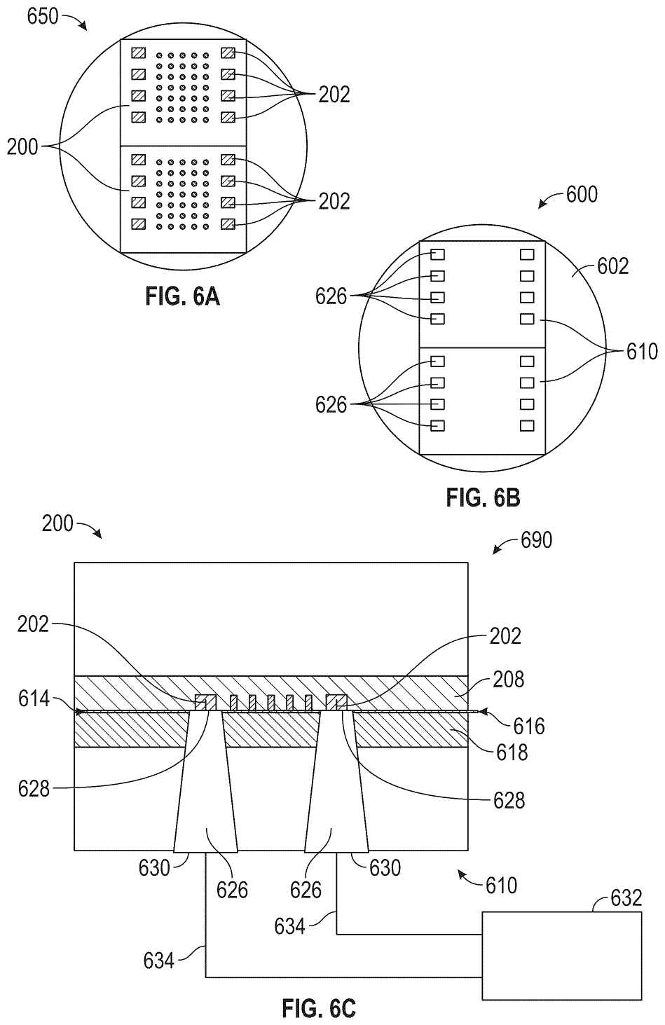

FIGS. 6A-6C illustrate various views of another implementation of a test assembly 600. The test assembly 600 can be utilized, for example, for testing device wafer with probe pad size of tens of microns or larger. The test assembly 600 can be used to test a device wafer 650. FIG. 6A illustrates a top schematic view of the device wafer 650. In some implementations, the device wafer 650 can include several semiconductor elements (e.g., semiconductor element 200 having probe pads 202) prior to singulation of the device wafer 650. Before and/or after testing, the device wafer 650 can be diced to form the semiconductor elements 200 having probe pads 202. For ease of illustration, the device wafer 650 can be shown as containing two semiconductor element 200 having probe pads 202. FIG. 6B illustrates and bottom view of probing elements 610 of the test assembly 600 having multiple channels 626 to contact probe pads 202. FIG. 6C schematically illustrates a cross-sectional side view of probing element 610 of the test assembly 600 and semiconductor element 200 after a process for forming a directly bonded structure, according to some implementations. Unless otherwise noted, components of FIGS. 6A-6C can be the same as or generally similar to like-numbered components of FIGS. 3-5C. For example, the test assembly 600 can include test interface substrate 602, base layer (see base layer 304 in FIG. 3), vias (see vias 306 in FIG. 3), conductive adhesive (see conductive adhesive 308 in FIG. 3), a probing element 610, layers (see routing layers 312 in FIG. 3), bonding surface 614, bonding interface 616, and nonconductive layers 618. In some implementations, the entirety of the device wafer 650 can be contacted and tested at the same time by the probing element 610.

As shown in FIG. 6C, the probing element 610 can be temporarily bonded (e.g., direct bonding) to the semiconductor element 200 of the device wafer 650. The probing element 610 can include a bonding surface 614 having nonconductive layers 618 (i.e., dielectric layers). The nonconductive layers 618 can comprise layers of non-conductive materials suitable for direct bonding, as described herein. A dielectric bond can be formed along a bonding interface 616 between the nonconductive layers 618 of the probing element 610 and the nonconductive layers 206 of the semiconductor element 200. In some implementations, the nonconductive layers 618, similar to nonconductive layers 318, 518, and, in some implementations, the nonconductive layer 206, can be treated to weaken the bond formed between nonconductive layers 618 and nonconductive layers 206. Additionally, the probing element 610 can include one or more channels 626 extending through the probing element 610. The channels 626 can receive a conductive liquid metal, also known as a post-transition metal, for providing electrical communication between the test assembly 600 and the probe pads 202 during testing of the semiconductor element 200. The combination of the channels 626 and conductive liquid metal can form a reconfigurable test contact, replacing the contact pads (e.g., contact pads 320 and/or contact pads 520) mentioned above. Conventional solid metal contact pads and/or probes can wear out quickly due to repeated mechanical contact with the semiconductor surfaces, which can lead to inaccuracies in test results and frequent replacements. Liquid metal probes, however, can conform to the shape of the contact pads (e.g., probe pads 202) on semiconductor devices (e.g., semiconductor element 200), providing a more reliable and less abrasive connection. This conformability can provide a more consistent electrical contact, which allows for precise measurements during testing. As previously mentioned, the channels 626 can be integrated into the test assembly 600 to guide the conductive liquid metal to specific contact points on the device wafer 650 such as the probe pads 202. The ability of conductive liquid metals to flow and self-heal allows said liquid metals to create temporary yet highly conductive pathways for testing signals. Additionally, by removing (e.g., pumping, siphoning, etc.) the conductive liquid metals from the channels 626, disconnecting from the probe pads 202 can be made easier.

The channels 626 can comprise an opening 628 that terminates at the bottom surface of the probing element 610. The opening 628 can expose the channel 626 to the probe pads 202 such that the liquid metal contacts the pads 202 and does not escape the channels 626. In some implementations, at an end 630, opposite the opening 628, the channels 626 fluidly connect to a reservoir 632, which stores the conductive liquid metal. In some implementations, the channels 626 are connected to the reservoir 632 via supply lines 634. The channels 626 can comprise various shapes and sizes, such as a conical channel in which the diameter tapers and/or gradually changes in width along the length of the channel, a cylindrical channel having a uniform diameter, rectangular and/or square channels, etc.

The conductive liquid metal can comprise any suitable conductive liquid metal such as gallium, indium, tin, zinc, bismuth, mercury, cadmium, thallium, and lead and/or any combination of said metals to form alloys. Conductive liquid metals, such as those mentioned above, combine metallic properties with fluidity at relatively low temperatures. Unlike conventional solid metals, conductive liquid metals can maintain a liquid state at temperatures close to and/or below room temperature. These metals are notable for their high electrical conductivity. Gallium, for example, has a melting point of just 29.76° C., making it liquid at slightly above room temperature. This property is shared by other alloys like Galinstan, a eutectic mixture of gallium, indium, and tin, which remains liquid down to −19° C. These liquid metals can conform to complex shapes, self-heal, and maintain conductivity, offering significant advantages.

After conducting the testing, the conductive liquid metal can be removed from the channels 626. The probing element 610 can be debonded from the semiconductor element 200 by separating the nonconductive layers 618 from the nonconductive layers 206. Additionally, the probe pads 202 and nonconductive layers 206 can be reconditioned to prepare the semiconductor element 200 for processing and/or bonding to the interposer 216. The combination of the weakened dielectric bond with the channels 626 can allow for testing the semiconductor element 200 without damaging the probe pads 202 and/or the semiconductor element 200.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 708a and/or 708b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

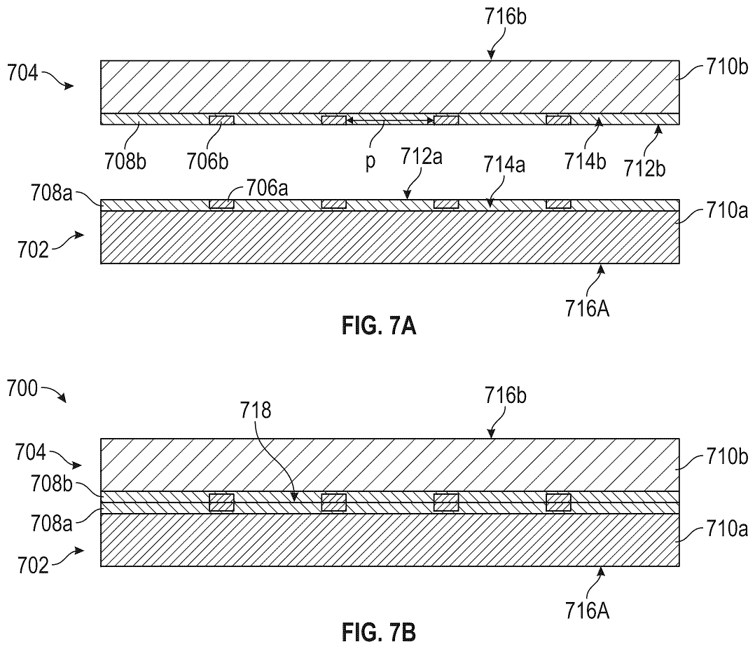

FIGS. 7A and 7B schematically illustrate cross-sectional side views of first and second elements 702, 704 prior to and after, respectively, a process for forming a directly bonded structure, and more particularly a hybrid bonded structure, according to some embodiments. In FIG. 7B, a bonded structure 700 comprises the first and second elements 702 and 704 that are directly bonded to one another at a bond interface 718 without an intervening adhesive. Conductive features 706a of a first element 702 may be electrically connected to corresponding conductive features 706b of a second element 704. In the illustrated hybrid bonded structure 700, the conductive features 706a are directly bonded to the corresponding conductive features 706b without intervening solder or conductive adhesive.

The conductive features 706a and 706b of the illustrated embodiment are embedded in, and can be considered part of, a first bonding layer 708a of the first element 702 and a second bonding layer 708b of the second element 704, respectively. Field regions of the bonding layers 708a, 708b extend between and partially or fully surround the conductive features 706a, 706b. The bonding layers 708a, 708b can comprise layers of non-conductive materials suitable for direct bonding, as described above, and the field regions are directly bonded to one another without an adhesive. The non-conductive bonding layers 708a, 708b can be disposed on respective front sides 714a, 714b of base substrate portions 710a, 710b.

The first and second elements 702, 704 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 702, 704, and back-end-of-line (BEOL) interconnect layers over such semiconductor portions. The bonding layers 708a, 708b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 710a, 710b, and can electrically communicate with at least some of the conductive features 706a, 706b. Active devices and/or circuitry can be disposed at or near the front sides 714a, 714b of the base substrate portions 710a, 710b, and/or at or near opposite backsides 716a, 716b of the base substrate portions 710a, 710b. In other embodiments, the base substrate portions 710a, 710b may not include active circuitry, but may instead comprise dummy substrates, passive interposers, passive optical elements (e.g., glass substrates, gratings, lenses), etc. The bonding layers 708a, 708b are shown as being provided on the front sides of the elements, but similar bonding layers can be additionally or alternatively provided on the back sides of the elements.

In some embodiments, the base substrate portions 710a, 710b can have significantly different coefficients of thermal expansion (CTEs), and bonding elements that include such different based substrate portions can form a heterogenous bonded structure. The CTE difference between the base substrate portions 710a and 710b, and particularly between bulk semiconductor (typically single crystal) portions of the base substrate portions 710a, 710b, can be greater than 5 ppm/° C. or greater than 10 ppm/° C. For example, the CTE difference between the base substrate portions 710a and 710b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 710a, 710b can comprise optoelectronic single crystal materials, including perovskite materials, that are useful for optical piezoelectric or pyroelectric applications, and the other of the base substrate portions 710a, 710b comprises a more conventional substrate material. For example, one of the base substrate portions 710a, 710b comprises lithium tantalate (LiTaO3) or lithium niobate (LiNbO3), and the other one of the base substrate portions 710a, 710b comprises silicon (Si), quartz, fused silica glass, sapphire, or a glass. In other embodiments, one of the base substrate portions 710a, 710b comprises a III-V single semiconductor material, such as gallium arsenide (GaAs) or gallium nitride (GaN), and the other one of the base substrate portions 710a, 710b can comprise a non-III-V semiconductor material, such as silicon (Si), or can comprise other materials with similar CTE, such as quartz, fused silica glass, sapphire, or a glass. In still other embodiments, one of the base substrate portions 710a, 710b comprises a semiconductor material and the other of the base substrate portions 710a, 710b comprises a packaging material, such as a glass, organic or ceramic substrate.

In some arrangements, the first element 702 can comprise a singulated element, such as a singulated integrated device die. In other arrangements, the first element 702 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 704 can comprise a singulated element, such as a singulated integrated device die. In other arrangements, the second element 704 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 702, 704 are shown, any suitable number of elements can be stacked in the bonded structure 700. For example, a third element (not shown) can be stacked on the second element 704, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 702. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 708a, 708b, the bonding layers 708a, 708b can be prepared for direct bonding. Non-conductive bonding surfaces 712a, 712b at the upper or exterior surfaces of the bonding layers 708a, 708b can be prepared for direct bonding by polishing, for example, by chemical mechanical polishing (CMP). The roughness of the polished bonding surfaces 712a, 712b can be less than 30 Å rms. For example, the roughness of the bonding surfaces 712a and 712b can be in a range of about 0.1 Å rms to 15 Å rms, 0.5 Å rms to 10 Å rms, or 1 Å rms to 5 Å rms. Polishing can also be tuned to leave the conductive features 706a, 706b recessed relative to the field regions of the bonding layers 708a, 708b.

Preparation for direct bonding can also include cleaning and exposing one or both of the bonding surfaces 712a, 712b to a plasma and/or etchants to activate at least one of the surfaces 712a, 712b. In some embodiments, one or both of the surfaces 712a, 712b can be terminated with a species after activation or during activation (e.g., during the plasma and/or etch processes). Without being limited by theory, in some embodiments, the activation process can be performed to break chemical bonds at the bonding surface(s) 712a, 712b, and the termination process can provide additional chemical species at the bonding surface(s) 712a, 712b that alters the chemical bond and/or improves the bonding energy during direct bonding. In some embodiments, the activation and termination are provided in the same step, e.g., a plasma to activate and terminate the surface(s) 712a, 712b. In other embodiments, one or both of the bonding surfaces 712a, 712b can be terminated in a separate treatment to provide the additional species for direct bonding. In various embodiments, the terminating species can comprise nitrogen. For example, in some embodiments, the bonding surface(s) 712a, 712b can be exposed to a nitrogen-containing plasma. Other terminating species can be suitable for improving bonding energy, depending upon the materials of the bonding surfaces 712a, 712b. Further, in some embodiments, the bonding surface(s) 712a, 712b can be exposed to fluorine. For example, there may be one or multiple fluorine concentration peaks at or near a bond interface 718 between the first and second elements 702, 704. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 700, the bond interface 718 between two non-conductive materials (e.g., the bonding layers 708a, 708b) can comprise a very smooth interface with higher nitrogen (or other terminating species) content and/or fluorine concentration peaks at the bond interface 718. In some embodiments, the nitrogen and/or fluorine concentration peaks may be detected using various types of inspection techniques, such as SIMS techniques. The polished bonding surfaces 712a and 712b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 708a and 708b can be directly bonded to one another without an adhesive. In some embodiments, the elements 702, 704 are brought together at room temperature, without the need for application of a voltage, and without the need for application of external pressure or force beyond that used to initiate contact between the two elements 702, 704. Contact alone can cause direct bonding between the non-conductive surfaces of the bonding layers 708a, 708b (e.g., covalent dielectric bonding). Subsequent annealing of the bonded structure 700 can cause the conductive features 706a, 706b to directly bond.

In some embodiments, prior to direct bonding, the conductive features 706a, 706b are recessed relative to the surrounding field regions, such that a total gap between opposing contacts after dielectric bonding and prior to anneal is less than 15 nm, or less than 10 nm. Because the recess depths for the conductive features 706a and 706b can vary across each element, due to process variation, the noted gap can represent a maximum or an average gap between corresponding conductive features 706a, 706b of two joined elements (prior to anneal). Upon annealing, the conductive features 706a and 706b can expand and contact one another to form a metal-to-metal direct bond.

During annealing, the conductive features 706a, 706b (e.g., metallic material) can expand while the direct bonds between surrounding non-conductive materials of the bonding layers 708a, 708b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 706a, 706b can comprise discrete pads, contacts, electrodes, or traces at least partially embedded in the non-conductive field regions of the bonding layers 708a, 708b. In some embodiments, the conductive features 706a, 706b can comprise exposed contact surfaces of TSVs (e.g., through silicon vias).

As noted above, in some embodiments, in the elements 702, 704 of FIG. 7A prior to direct bonding, portions of the respective conductive features 706a and 706b can be recessed below the non-conductive bonding surfaces 712a and 712b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 706a, 706b or to average depths of the recesses relative to local non-conductive field regions. Even for an individual conductive feature 706a, 706b, the vertical recess can vary across the feature, and so can be measured at or near the lateral middle or center of the cavity in which a given conductive feature 706a, 706b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 706a, 706b across the direct bond interface 718 (e.g., small or fine pitches for regular arrays).

In some embodiments, a pitch p of the conductive features 706a, 706b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 706a and 706b to one of the lateral dimensions (e.g., a diameter) of the bonding pad is less than 20, or less than 10, or less than 5, or less than 3 and sometimes desirably less than 2. In various embodiments, the conductive features 706a and 706b and/or traces can comprise copper or copper alloys, although other metals may be suitable, such as nickel, aluminum, or alloys thereof. The conductive features disclosed herein, such as the conductive features 706a and 706b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 702, 704, as shown, the orientations of one or more conductive features 706a, 706b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 706b in the bonding layer 708b (and/or at least one internal conductive feature, such as a BEOL feature) of the upper element 704 may be tapered or narrowed upwardly, away from the bonding surface 712b. By way of contrast, at least one conductive feature 706a in the bonding layer 708a (and/or at least one internal conductive feature, such as a BEOL feature) of the lower element 702 may be tapered or narrowed downwardly, away from the bonding surface 712a. Similarly, any bonding layers (not shown) on the backsides 716a, 716b of the elements 702, 704 may taper or narrow away from the backsides, with an opposite taper orientation relative to front side conductive features 706a, 706b of the same element.

As described above, in an anneal phase of hybrid bonding, the conductive features 706a, 706b can expand and contact one another to form a metal-to-metal direct bond. In some embodiments, the materials of the conductive features 706a, 706b of opposite elements 702, 704 can interdiffuse during the annealing process. In some embodiments, metal grains grow into each other across the bond interface 718. In some embodiments, the metal is or includes copper, which can have grains oriented along the 111 crystal plane for improved copper diffusion across the bond interface 718. In some embodiments, the conductive features 706a and 706b may include nanotwinned copper grain structure, which can aid in merging the conductive features during anneal. There is substantially no gap between the non-conductive bonding layers 708a and 708b at or near the bonded conductive features 706a and 706b. In some embodiments, a barrier layer may be provided under and/or laterally surrounding the conductive features 706a and 706b (e.g., which may include copper). In other embodiments, however, there may be no barrier layer under the conductive features 706a and 706b.

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementations. Conversely, various features that are described in the context of a single embodiment also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more embodiments.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further implementations. The accompanying claims and their equivalents are intended to cover such forms or modifications as would fall within the scope and spirit of the disclosure.

Several illustrative examples of testing assemblies and/or probe cards and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles and the novel features disclosed herein.

1.-96. (canceled)

97. A probe card for probing a semiconductor substrate, the probe card comprising:
a probing element having a hybrid bonding surface that removably hybrid bonds to a semiconductor element, the hybrid bonding surface of the probing element comprising a nonconductive layer and contact pads at least partially embedded in the nonconductive layer;
wherein the contact pads of the probing element are bonded to probe pads of the semiconductor element; and
wherein the nonconductive layer of the probing element is bonded to a nonconductive layer of the semiconductor element.

98. The probe card of claim 97, further comprising an optical device connected to the hybrid bonding surface.

99. The probe card of claim 97, wherein a conductive material is deposited over the contact pads.

100. The probe card of claim 99, wherein the conductive material comprises a lower melting point than the contact pads.

101. The probe card of claim 97, further comprising:
a test interface substrate;
wherein the probing element further comprises a base layer having one or more vias extending through the base layer and routing layers having a first surface and a second surface opposite the first surface, the first surface of the routing layers attached to the base layer; and
wherein the one or more vias of the base layer electrically connect the test interface substrate and the probing element.

102. The probe card of claim 101, wherein the test interface substrate comprises testing circuitry configured to test physical functionality, electrical connectivity and functionality, and optical functionality of the semiconductor element.

103. The probe card of claim 101, further comprising a conductive adhesive connecting the one or more vias of the base layer to the test interface substrate.

104. The probe card of claim 97, further comprising elastic biasing members connected to the contact pads and configured to cause reversible contact between the contact pads of the probing element and the probe pads of the semiconductor element.

105. The probe card of claim 97, further comprising one or more channels in communication with the contact pads, wherein the one or more channels are configured for liquid metal injection for providing electrical communication between the probing element and the probe pads of the semiconductor element during probing of the semiconductor element.

106. A probe card for probing a semiconductor substrate, the probe card comprising:
a probing element having a hybrid bonding surface that is prepared to removably hybrid bond to a semiconductor element, the hybrid bonding surface comprising a nonconductive layer and contact pads at least partially embedded in the nonconductive layer, wherein the contact pads of the probing element are configured to be bonded to probe pads of the semiconductor element, and wherein the nonconductive layer of the probing element is configured to be bonded to a nonconductive layer of the semiconductor element; and
elastic biasing members connected to the contact pads and configured to cause reversible contact between the contact pads of the probing element and the probe pads of the semiconductor element.

107. The probe card of claim 106, wherein a conductive material is deposited over the contact pads.

108. The probe card of claim 106, further comprising:
a test interface substrate;
wherein the probing element further comprises a base layer having one or more vias extending through the base layer and routing layers having a first surface and a second surface opposite the first surface, the first surface of the routing layers attached to the base layer; and
wherein the one or more vias of the base layer electrically connect the test interface substrate and the probing element.

109. The probe card of claim 108, wherein the test interface substrate comprises testing circuitry, wherein the testing circuitry tests physical functionality, electrical connectivity and functionality, and optical functionality of the semiconductor element.

110. The probe card of claim 108, further comprising a conductive adhesive connecting the one or more vias of the base layer to the test interface substrate.

111. A probe card for probing a semiconductor substrate, the probe card comprising:
a probing element having a hybrid bonding surface that is prepared to removably hybrid bond to a semiconductor element, the hybrid bonding surface comprising a nonconductive layer and contact pads at least partially embedded in the nonconductive layer, wherein the contact pads of the probing element are to be bonded to probe pads of the semiconductor element, and wherein the nonconductive layer of the probing element is configured to be bonded to a nonconductive layer of the semiconductor element; and
one or more channels in communication with the contact pads, wherein the one or more channels are configured for liquid metal injection for providing electrical communication between the probing element and the probe pads of the semiconductor element during probing of the semiconductor element.

112. The probe card of claim 111, wherein the injected liquid metal comprises at least one of gallium, indium, tin, zinc, bismuth, mercury, cadmium, thallium, and lead.

113. The probe card of claim 111, wherein a conductive material is deposited over the contact pads.

114. The probe card of claim 111, further comprising:
a test interface substrate;
having a base layer, wherein the test interface substrate comprises one or more vias extending through the test interface substrate;
wherein the probing element further comprises a base layer having one or more vias extending through the base layer and routing layers having a first surface and a second surface opposite the first surface, the first surface of the routing layers attached to the base layer; and
wherein the one or more vias of the base layer electrically connect the test interface substrate and the probing element.

115. The probe card of claim 114, wherein the test interface substrate comprises testing circuitry, wherein the testing circuitry tests physical functionality, electrical connectivity and functionality, and optical functionality of the semiconductor element.

116. The probe card of claim 114, further comprising a conductive adhesive connecting the one or more vias of the base layer to the test interface substrate.
